(19) United States
(12) Patent Application Publication
(10) Pub. No.: US 2014/0266228 A1
(43) Pub. Date: Sep. 18, 2014

(54) ACTIVE MEASUREMENT OF BATTERY EQUIVALENT SERIES RESISTANCE

(71) Applicant: QUALCOMM Incorporated, San Diego, CA (US)

(72) Inventors: Paolo Baruzzi, Santa Clara, CA (US); Georgios K Paparrizos, Foster City, CA (US); Giovanni Garcea, San Jose, CA (US)

(73) Assignee: QUALCOMM Incorporated, San Diego, CA (US)

(21) Appl. No.: 14/169,471

(22) Filed: Jan. 31, 2014

Related U.S. Application Data
(60) Provisional application No. 61/798,570, filed on Mar. 15, 2013.

(51) Int. Cl. G01R 31/36

(52) U.S. Cl. CPC G01R 31/3662
USPC 324/430

(57) ABSTRACT

A circuit for measuring the equivalent series resistance (ESR) of a battery includes taking measurements of battery current and battery voltage. A controller may control the taking of the measurements. A load generator may be activated to produce a current pulse to the battery to provide an explicit current transient under certain operating conditions of the battery.

### CROSS REFERENCE TO RELATED APPLICATIONS

The present disclosure claims priority to U.S. Provisional App. No. 61/798,570 filed Mar. 15, 2013, the content of which is incorporated herein by reference in its entirety for all purposes.

The present disclosure is related to (1) a non-provisional application entitled “STATE OF CHARGE (SOC) DISPLAY FOR RECHARGEABLE BATTERY” (Applicant ref no. 132005U2) filed herewith and (2) U.S. application Ser. No. 13/719,062 entitled “BATTERY FUEL GAUGE” filed Dec. 18, 2012 the content of both of which are incorporated herein by reference in their entirety for all purposes.

### BACKGROUND

Unless otherwise indicated, the foregoing is not admitted to be prior art to the claims recited herein and should not be construed as such.

The amount of electric charge that a battery can store is typically referred to as the battery's “capacity”. The state of charge (SoC) of a battery expresses the battery's present capacity (how much electric charge is presently stored) as a percentage of the battery's maximum capacity (the maximum amount of electric charge that can be stored). The SoC of a battery is dependent on various factors including, inherent chemical characteristics of the battery, characteristics of the electrical system in which the battery is installed, and operating conditions of the battery.

An important factor in estimating SoC is the battery's equivalent series resistance (ESR). Conventional techniques for determining battery ESR include the use of lookup tables stored in the circuitry for managing the battery. Data tables are limited in the amount of information they represent. Data tables typically represent one kind of battery, they are limited in how much to the battery they can characterize, and so on. In order to accommodate a wider range of batteries, additional data tables must be used; larger tables are required in order to more fully and accurately characterize each battery. The potentially high memory requirements for storing lookup tables are at odds with the requirements of contemporary low-cost and small-sized mobile electronic devices.

### SUMMARY

In accordance with the present disclosure, battery ESR of a battery powering an electronic device may be determined using measurements of battery current and battery voltage, without using data from any data tables stored in the electronic device. The battery current and battery voltage measurements used to determine battery ESR may be made periodically. In some embodiments, for example, the passage of time may trigger battery current and battery voltage measurements.

In some embodiments, a current pulse may be applied to the battery at around the same time the battery current and battery voltage measurements are taken in response to detected operating conditions of the battery. For example, a current pulse may be applied during a charging cycle of the battery. Temperature readings relating to the battery may trigger applying a current pulse. The operating state of the device powered by the battery may trigger a current pulse, and so on. In some embodiments, the current pulse may serve to reduce the amount of charge current flowing into the battery during charge mode, or to increase the amount of discharge current flowing out of the battery during discharge mode.

The following detailed description and accompanying drawings provide a better understanding of the nature and advantages of the present disclosure.

### BRIEF DESCRIPTION OF THE DRAWINGS

With respect to the discussion to follow and in particular to the drawings, it is stressed that the particulars shown represent examples for purposes of illustrative discussion, and are presented in the cause of providing a description of principles and conceptual aspects of the present disclosure. In this regard, no attempt is made to show implementation details beyond what is needed for a fundamental understanding of the present disclosure. The discussion to follow, in conjunction with the drawings, make apparent to those of skill in the art how embodiments in accordance with the present disclosure may be practiced. In the accompanying drawings:

FIG. 1 shows a high level block circuit diagram for generating battery ESR in accordance with principles of the present disclosure.

FIGS. 1A-1E illustrate example configurations of a circuit of the present disclosure in an electronic device.

FIG. 2 shows a process flow for determining battery ESR in accordance with the present disclosure.

FIG. 3 illustrates an example of the timing of current and voltage measurements in accordance with some embodiments.

FIG. 4 illustrates an example of the timing of current pulses in accordance with some embodiments.

FIG. 5 illustrates additional details of load generator 112.

FIG. 6 illustrates examples of current pulses in accordance with the present disclosure.

### DETAILED DESCRIPTION

In the following description, for purposes of explanation, numerous examples and specific details are set forth in order to provide a thorough understanding of the present disclosure. It will be evident, however, to one skilled in the art that the present disclosure as expressed in the claims may include some or all of the features in these examples, alone or in combination with other features described below, and may further include modifications and equivalents of the features and concepts described herein.

FIG. 1 is a schematic representation of a circuit 100 in accordance with the present disclosure for generating a battery ESR estimate (ESR) when a battery 10 is connected to the circuit. The battery 10 may be a singe cell configuration, or may be a multiple cell configuration sometimes referred to as a “battery pack”. Typically, the circuit 100 may be part of an electronic device (not shown) to which the battery 10 is connected; e.g., to be powered by the battery, for charging the battery, etc. The circuit 100 may operate with the battery fuel gauge system 14 for determining SoC. For example, the ESR may be an input to a battery model 16 in the fuel gauge system 14. In some embodiments, the circuit 100 may be separate from the circuitry of the fuel gauge system 14. In other embodiments, the circuit 100 may be incorporated into the circuitry of the fuel gauge system 14, and so on.

Referring for a moment to FIGS. 1A-1E, illustrative, though not exhaustive, examples of configurations of circuit 100 in an electronic device 20 are shown. FIG. 1A shows the circuit 100 and fuel gauge system 14 as separate components in device 20 (e.g., circuit 100 and fuel gauge system 14 may be separate IC packages assembled on a printed circuit board). FIG. 1B illustrates that circuit 100 may be part of the circuitry comprising fuel gauge system 14. FIG. 1C illustrates the converse, where circuitry comprising fuel gauge system 14 may be incorporated in circuit 100. FIG. 1D illustrates an example of an electronic device 20 that does not use a fuel gauge system. FIG. 1E illustrates a configuration where circuit 100 is provided on an electronic device 20′ separate from electronic device 20. Though not illustrated, in some embodiments, the circuit 100 (and/or the fuel gauge 14) may be incorporated in a battery pack comprising several cells. Still other configurations can be envisioned.

Returning to FIG. 1, in some embodiments, the circuit 100 may include a current sensor 104, a voltage sensor 106, and a temperature sensor 108. The circuit 100 may further include a load generator 112 to introduce a controllable current load pulse to the battery 10, additional details for which will be discussed below. A controller 102 may receive input from the current sensor 104, voltage sensor 106, and temperature sensor 108 to control various aspects of the circuit 100 to generate an estimate of the ESR. In some embodiments, the controller 102 may receive additional signals, such as operating mode; e.g., charge mode, discharge mode, etc. The controller 102 may comprise any suitable data processing logic, such as, but not limited to, a digital signal processor, a microprocessor, etc. A suitable memory 114 (e.g., non-volatile memory) may be provided to store information such as program instructions, preprogrammed data, intermediate data, and the like.

The current sensor 104 may acquire a measure of the current flowing through the battery 10. In some embodiments, the current sensor 104 may use a sense resistor 12 to detect the flow of current (I_{BATT}) through the battery 10. The current sensor 104 may employ an analog-to-digital converter (ADC) to produce a current measurement I_{BATT} expressed in digital format.

The voltage sensor 106 may acquire a measure of the voltage (V_{BATT(meas)}) of the battery 10. In some embodiments, the voltage sensor 106 may include an ADC to produce a voltage measurement V_{BATT(meas)} expressed in digital format.

The temperature sensor 108 may comprise a temperature sensing element 108a and circuitry 108b (e.g., an ADC) for producing output indicative of a temperature of the battery. In some embodiments, the temperature sensing element 108a may be positioned near the battery 10 to measure ambient temperature. In other embodiments, the temperature sensing element 108a may be incorporated in the battery 10. In still other embodiments, where the battery 10 is configured as a battery pack of several cells, the temperature sensing element 108a may be incorporated in the battery pack.

The load generator 112 may be any suitable circuit design for generating a current pulse load that can be applied to the battery 10. In some embodiments, if the battery 10 is in charge mode (e.g., receiving a charge current to charge the battery), then the load generator 112 may generate a current pulse load that reduces the amount of charge current entering the battery. If the battery 10 is in discharge mode (e.g., the battery is powering electronic components in the device 20) or standby mode, then the load generator 112 may generate a current pulse load that increases the current flow out of the battery.

In some embodiments, the load generator 112 may receive a pulse control signal from the controller 102. The load generator 112 may include programmable capability to generate one or more current pulses of a given pulse width and a given pulse height. Pulse frequency and duty cycle can be controlled. In some embodiments, for example, the pulse control signal may include information to configure pulses generated by the load generator 112.

Referring to FIG. 2, a process flow explains an example of processing in the controller 102 in accordance with embodiments of the present disclosure. Thus, at block 202, in some embodiments, the controller 102 may signal the current sensor 104 and the voltage sensor 106 to take respective current and voltage measurements. In other embodiments, where the electronic device (e.g., 20, FIG. 1A) incorporates a fuel gauge (e.g., 14), current and voltage measurements may be made by the fuel gauge system as part of a process for determining SoC. Accordingly, those current and voltage measurements may be used by the controller 102 to produce an estimated battery ESR. In such embodiments, circuit 100 may omit the current sensor 104 and voltage sensor 106 circuits in order to save space.

At block 204, a certain amount time may pass (delay) before making a second set of current and voltage measurements (block 206). The amount of delay may be based on any suitable factor or set of factors. In some embodiments, for example, the delay between measurements in blocks 202 and 206 may vary from one set of measurements to the next. The delay(s) may be programmed into a non-volatile memory by a system designer, and so on. In an embodiment, for example, where the fuel gauge system 14 provides the current and voltage measurements, the delay between measurements in blocks 202 and 206 may be tied to the frequency at which the fuel gauge system takes the measurements.

At block 208, the controller 102 may make a determination whether a difference between the first measurements and the second measurements exceeds a predetermined threshold. The predetermined threshold may programmed into non-volatile memory by a system designer, for example. In some embodiments, the determination in block 208 is based on whether the absolute difference between the first current measurement and the second current measurement exceeds a given threshold. The test in block 208 may be desirable in order to reduce the effects of noise in the ADC conversion process. In some embodiments, the determination may be further based, though not necessarily, on a difference between the first and second voltage measurements.

If block 208 evaluates to YES, then the controller 102 may compute an ESR value at block 210. In some embodiments, for example, the ESR may be computed according to the following:

$$ESR = \frac{{V}_{t - 1} - {V}_{t}}{{I}_{t - 1} - {I}_{t}} ,$$

where, (t−1) indicates first (previous) voltage (V) and current (I) measurements and (t) indicates second (subsequent) voltage and current measurements. The computed value represents an estimate of the ESR, which the controller 102 may output as the battery ESR.

In some embodiments, it may be desirable to account for noisy conditions and avoid updating the estimated ESR too frequently. Accordingly, a maximum increase value (Max_{increase}) and a maximum decrease value (Max_{decrease}) may be maintained. The maximum increase value (Max_{increase}) represents the largest increase of a computed ESR from a previously computed ESR, and similarly for the maximum decrease value (Max_{decrease}). In some embodiments, these minimum and maximum values may be provided by a system designer and stored in non-volatile memory.

In other embodiments, these values may be periodically updated. For example, in block 210, when the ESR is computed, a difference between the computed ESR and the last computed ESR is determined. If there is an increase from the last ESR and the increase is >Max_{increase}, then the Max_{increase} value may be updated with the difference. If there is a decrease from the last ESR and the decrease is <Max_{decrease}, then the Max_{decrease} value may be updated with the difference.

At block 212, a determination may be made whether to filter the ESR computed at block 210. For example, if the ESR value computed in block 210 is compared with the previously computed ESR value and meets the following condition:

Max_{increas}>ESR>Max_{decrease}

then the ESR that is output (block 214) by controller 102 may be determined in accordance with:

$${ESR}_{output} = \frac{{ESR}_{computed} + {ESR}_{previous}}{2} ,$$

where ESRₚᵣₑᵥᵢₒᵤₛ refers to the previously output ESR value (not the previously computed ESR value). It will be appreciated that other computations may be used to filter the computed ESR. If the determination is block 212, on the other hand, evaluates to NO, then in some embodiments, the controller 102 may output the previously output ESR value.

At block 216, the controller 102 may delay for a time before repeating the foregoing process. The amount of delay may be based on any suitable factor or set of factors. In some embodiments, the delay may vary from one loop through the process to the next. The delay(s) may be programmed into a non-volatile memory by a system designer, and so on.

An advantageous aspect of the foregoing is that the data used to compute the estimated ESR is taken from actual current and voltage measurements. Accordingly, data tables, which can consume a large amount of space need not be provided nor maintained in the electronic device for the purpose of ESR estimates.

FIG. 3 illustrates an example in which current and voltage measurements (blocks 202, 206) are provided by and synchronized with the fuel gauge system 14. Here, each update period of the fuel gauge system 14 involves making various measurements in order to produce an estimate of SoC. The sync current conversion and sync voltage conversion measurements may be further used as the current and voltage measurements for controller 102. The delay in blocks 204 and 206 may be tied to the SoC update periods in the fuel gauge system 14. For example, measurements may be used by the controller from every update period. Or, measurements from every other update period may be used, and so on. It is noted of course, that the circuit 100 need not be used with a fuel gauge system, and may operate independently of a fuel gauge.

Referring for a moment to FIG. 1, in some situations, it may be desirable to create a suitable current transient in order make adequate battery current and battery voltage measurements that can be used to compute a valid ESR estimate. One such situation may exist, for example, when the electronic device (e.g., 20) is in “stand-by” mode in order to conserve battery charge. Current consumption is typically low during stand-by mode, and so adequate measurable current transients are less likely. In some embodiments, the controller 102 may receive a stand-by indication signal (e.g., operating mode signal, FIG. 1) from other circuitry in the electronic device that indicates when the electronic device has gone into a stand-by mode or other low power mode so that the controller 102 can know when to generate a current pulse load.

Another circumstance that may call for creating a current transient is detection of a temperature reading or change in temperature greater than some predefined threshold; e.g., programmed into non-volatile memory by a system designer. Since ESR is strongly dependent on temperature, when a sufficient change in temperature is detected, it may be desirable to create a current transient condition so that adequate current and voltage measurements can be taken in order to generate a valid ESR estimate. In some embodiments, the controller 102 may receive a temperature reading from the temperature sensor 108 that indicates a temperature of the battery.

Still another situation may arise in charge mode, when the battery is being charged. Here, a current transient may be introduced to disturb the relatively constant charging current that is flowing into the battery. Conversely, in discharge mode, where the battery may be powering electronic components in the device 20, the relatively constant discharge current flowing out of the battery may be disturbed with a current transient.

The controller 102 may generate a pulse control signal to signal the load generator 112 to produce a current pulse (pulse load). In some embodiments, the pulse load may be applied to the battery 10 to increase the outflow of current from the battery (e.g., during standby mode or discharge mode), or to reduce the flow of current into the battery (e.g., during charge mode). Concurrently with the pulse load, current and voltage measurements on the battery 10 may be taken (e.g., using current sensor 104 and voltage sensor 106). The pulse load may be generated only for the first current and voltage measurements (block 202), or each time current and voltage measurements are made (blocks 202, 206).

Generally, the pulse load is synchronized with the current and voltage conversion; e.g., ADC conversions for making respective current and voltage measurements. In some embodiments, for example, the pulse load may be initiated at the same time that the conversion begins; in other embodiments, the pulse load may be initiated slightly before or after the conversion begins. FIG. 4 illustrates an example of a pulse load that is synchronized with the update periods of the fuel gauge system 14.

The pulse load may be controlled in various aspects in addition to when it is initiated. In some embodiments, for example, the pulse control signal generated by the controller 102 may specify various parameters of the pulse load. For example, the pulse load duration may be controlled; the pulse load may have a duration that is shorter than, equal to, or greater than the respective conversion times of the current and voltage measurements. The pulse load amplitude (height) may be controlled. In some embodiments, a single pulse load may be generated during the current and voltage measurement. In other embodiments, one or more additional pulses may be generated during the conversion process. The duty cycle (pulse on-time as a percentage of pulse period) may vary from one pulse load to another. Still other parameters of the pulse load may be controlled.

Timers (hardware-based or software-based) may be employed to control how often pulse loads are generated. For example, controller 102 may employ a software timer to control when to issue a pulse control signal to the load generator 112. In some embodiments, it may be important to control how often pulse loads are generated in order that average current consumption of the battery 10 is not badly affected.

FIG. 5 shows an illustrative embodiment of the pulse load generator 112 in accordance with the present disclosure. Control logic 502 receives a pulse control signal from controller 102 (FIG. 1) and a charging signal from charging circuit 504. The charging signal, for example, may indicate whether the battery 10 is in charge mode or discharge mode. In charge mode, when the charging circuit 504 is providing a charge current to the battery 10, the control logic 502 may operate the charging circuit 504 to reduce the amount of charge current flowing into the battery in response to receiving a pulse control signal from the controller 102 (FIG. 1). Referring to FIG. 6, for example, the current pulse may manifest itself as a pulse dip in the charging current during charge mode. Conversely, in discharge mode, the control logic 502 may operate pulse generator 506 to increase the flow of current out of the battery 10 in response to receiving a pulse control signal from the controller 102. Referring again to FIG. 6, the current pulse in discharge mode may manifest as an increase in the flow of current out of (negative current) the battery 10 during discharge mode. For example, in some embodiments, the pulse generator 506 may provide current path to ground for a period of time (e.g., duration of the pulse load) to draw additional current out of the battery 10.

The above description illustrates various embodiments of the present disclosure along with examples of how aspects of the particular embodiments may be implemented. The above examples should not be deemed to be the only embodiments, and are presented to illustrate the flexibility and advantages of the particular embodiments as defined by the following claims. Based on the above disclosure and the following claims, other arrangements, embodiments, implementations and equivalents may be employed without departing from the scope of the present disclosure as defined by the claims.

We claim the following:

1. A method in a circuit to determine an equivalent series resistance (ESR) of a battery, the method comprising:
measuring, at a first time, a first current flow through the battery to obtain a first current measurement, when the battery is connected to the circuit;
measuring a first voltage across the battery concurrently with measuring the first current flow to obtain a first voltage measurement;
measuring, at a second time, a second current flow through the battery to obtain a second current measurement;
measuring a second voltage across the battery concurrently with measuring the second current flow to obtain a second voltage measurement; and
when a difference between the first current measurement and the second current measurement exceeds a predetermined value, then computing the ESR by dividing a difference between the first and second voltage measurements by a difference between the first and second current measurements.

2. The method of claim 1 wherein computing the ESR is performed without obtaining data from a data table.

3. The method of claim 1 further comprising applying a current pulse to the battery synchronously with measuring the first current flow, wherein the current pulse reduces a charge current flowing into the battery in charge mode and increases current flowing out of the battery in discharge mode.

4. The method of claim 1 further comprising applying a current pulse to the battery synchronously with measuring the second current flow.

5. The method of claim 1 wherein measuring the first current flow and measuring the second current flow are performed during a constant current charging phase of a battery charging cycle.

6. The method of claim 5 further comprising applying a current pulse to the battery concurrently with measuring the first current flow or measuring the second current flow.

7. The method of claim 1 further comprising applying a current pulse to the battery concurrent with measuring the first current flow or measuring the second current flow when a device the incorporates the circuit is operating in a stand-by mode.

8. The method of claim 1 further comprising applying a current pulse to the battery concurrent with measuring the first current flow or measuring the second current flow based on a temperature of the battery.

9. A circuit comprising a controller having a current measurement input to receive battery current measurements from a current sensor and a voltage measurement input to receive battery voltage measurements from a voltage sensor, wherein the controller is further configured to:
receive, at a first time, a first battery current measurement from the current sensor and a first battery voltage measurement from the voltage sensor;
receive, at a second time, a second battery current measurement from the current sensor and a second battery voltage measurement from the voltage sensor; and
compute a battery ESR of a battery connected to the circuit by dividing a difference between the first and second battery voltage measurements by a difference between the first and second battery current measurements, when a difference between the first battery current measurement and the second battery current measurement exceeds a predetermined value.

10. The circuit of claim 9 further comprising a load generator in communication with the controller, the load generator configured to apply a current pulse to the battery in response to receiving a control signal from the controller.

11. The circuit of claim 10 wherein the controller is configured to cause the load generator to apply a current pulse to the battery synchronously with a measurement that produces the first battery current measurement.

12. The circuit of claim 10 wherein the controller further has an input that indicates charging mode of the battery, wherein the controller is configured to cause the load generator to apply a current pulse to the battery when the charging mode is a constant current mode.

13. The circuit of claim 10 wherein the controller further has an input that indicates an operating mode of an electronic device that incorporates the circuit, wherein the controller is configured to cause the load generator to apply a current pulse to the battery when the operating mode is a stand-by mode.

14. The circuit of claim 10 wherein the controller further has an input to receive a temperature measurement from a temperature sensor, wherein the controller is configured to cause the load generator to apply a current pulse to the battery when a temperature difference exceeding a predetermined value has been detected.

15. The circuit of claim 14 further comprising the temperature sensor.

16. The circuit of claim 9 further comprising the current sensor.

17. The circuit of claim 9 further comprising the voltage sensor.

18. A circuit for determining battery ESR of a battery comprising:
first means for measuring a battery current through a battery;
second means for measuring a battery voltage across the battery; and
third means for controlling when a battery current measurement and a battery voltage measurement are taken, wherein a first battery current measurement is taken at a first time and a first battery voltage measurement is taken concurrently with taking the first battery current measurement, wherein a second battery current measurement is taken at a second time and a second battery voltage measurement is taken concurrently with taking the second battery current measurement,
wherein, when a difference between the first battery current measurement and the second battery current measurement exceeds a predetermined value, then computing the ESR by dividing a difference between the first and second battery voltage measurements by a difference between the first and second battery current measurements.

19. The circuit of claim 18 further comprising fourth means for applying a current pulse to the battery under control of the third means, wherein a current pulse is applied synchronously with measuring battery current.

20. The circuit of claim 19 wherein the current pulse is applied to the battery depending on an operating mode of the battery.
